(19) United States
(12) Patent Application Publication
(10) Pub. No.: US 2017/0131362 A1
(43) Pub. Date: May 11, 2017

(54) METHOD FOR DETERMINING REMAINING BATTERY LIFE OF AT LEAST ONE ELECTROCHEMICAL CELL OR BATTERY ACROSS A LARGE TEMPERATURE RANGE

(71) Applicant: Digi International Inc., Minnetonka, MN (US)

(72) Inventors: Mark H. Wickham, Eagan, MN (US); Nathan B. Carlson, Fridley, MN (US)

(21) Appl. No.: 14/935,998

(22) Filed: Nov. 9, 2015

(51) Int. Cl. G01R 31/36; H01M 10/48; H01M 10/42; G01N 25/00

(52) U.S. Cl. CPC G01R 31/3679; G01R 31/3689; G01R 31/3658; G01N 25/00; H01M 10/48; H01M 10/4285

(57) ABSTRACT

A method to determine if at least one electrochemical cell is in a late-life stage of a life of the at least one electrochemical cell is provided. the method includes monitoring a voltage of the at least one electrochemical cell while powering at least one load; and determining a lowest voltage of the at least one electrochemical cell measured while powering the at least one load.

### BACKGROUND

Battery powered devices eventually exhaust the powering battery and the battery must be recharged or replaced for the device to operate. It is useful to be able to measure how much of the battery charge remains to allow an operators to predict when replacement of the battery is necessary. For remote devices this is especially important.

Many battery powered devices use smart battery modules that contain circuitry that measures battery use and reports the battery condition to the attached device. This circuit remains with the battery (to form a smart battery) and to monitor the current flow from the battery. Because of the contained circuitry and packaging, the smart battery modules are more expensive than simple cells or batteries. Smart battery modules are typically only used on rechargeable batteries because of the high cost.

Some prior art techniques measure the rest voltage of the battery. Some batteries reduce their output voltage as they are used. Other batteries, such as Lithium chemistries, retain their voltage all the way to the very end, and the voltage only drops significantly after 99% of the battery charge has been depleted. Attempting a curve fit of the voltage over life of this latter type of battery is meaningless since the graph is so flat that 100% and 1% have the same voltage within measurement error. Compensating voltage over temperature does not improve the predictions.

Some prior art techniques use coulomb counters that measure current outflow from a battery. These techniques are costly. In many cases, the battery is used while not connected to the coulomb counter, or stored during which time the capacity of the battery is reduced. If the battery is stored in extreme temperatures, the battery capacity can be reduced very quickly while disconnected from the coulomb counter and the battery user is unaware the battery has died. Additionally, the replacement of the battery with another invalidates the coulomb counters if the coulomb counter is not part of the battery module (i.e., not part of a smart battery).

### SUMMARY

The present application provides a method to determine if at least one electrochemical cell is in a late-life stage of a life of the at least one electrochemical cell. the method includes monitoring a voltage of the at least one electrochemical cell while powering at least one load; and determining a lowest voltage of the at least one electrochemical cell measured while powering the at least one load.

### DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 shows life stages of an exemplary life of an electrochemical cell/battery in accordance with the present application;

FIGS. 2A-2D show various embodiments of systems to determine if an electrochemical cell/battery is in a late-life stage of the life of the electrochemical cell/battery in accordance with the present application;

FIG. 3 shows an embodiment of a method to determine if an electrochemical cell/battery is in a late-life stage of the life of the electrochemical cell in accordance with the present application;

FIG. 4 shows a plurality of minimum-powering voltages for a respective plurality of components in the device;

FIG. 5 shows a plurality of plots of minimum-powering voltages as a function of temperature for a respective plurality of components in the device over a desired temperature range; and

FIGS. 6-11 show various embodiments of systems to determine if an electrochemical cell/battery is in a late-life stage of the life of the respective electrochemical cell/battery in accordance with the present application.

In accordance with common practice, the various described features are not drawn to scale but are drawn to emphasize specific features relevant to the exemplary embodiments.

### DETAILED DESCRIPTION

In the following detailed description, reference is made to the accompanying drawings that form a part hereof, and in which is shown by way of illustration specific illustrative embodiments. However, it is to be understood that other embodiments may be utilized and that logical, mechanical, and electrical changes may be made. Furthermore, the method presented in the drawing figures and the specification is not to be construed as limiting the order in which the individual steps may be performed. The following detailed description is, therefore, not to be taken in a limiting sense.

The embodiments described below measure the voltage of an electrochemical cell or battery while the cell or battery is powering a load (i.e., under load) are used interchangeably herein. A battery includes a plurality of electrochemical cells so the term “at least one electrochemical cell” refers to both one electrochemical cell and a battery. The term cell/battery is used herein to refer to one of a cell or a battery. The term cells/batteries is used herein to refer to one of: a plurality of cells; a plurality of batteries; or at least one cell and at least one battery. An electrochemical cell is also referred to herein as a cell. The technology described herein is applicable to any type of cell and battery. For example, the cell or battery can include, but is not limited to, a galvanic cell, an electrolytic cell, a fuel cell, an alkaline battery, a lead-acid battery, a lithium ion battery. Primary or rechargeable cells/batteries can be used.

The charge level (also referred to as “condition”) of a cell/battery indicates how much energy can the battery deliver from its present state. The capacity of a cell/battery indicates how much energy the cell/battery can deliver from a fully charged state; the capacity is independent of the current state of charge. Both the capacity and condition of the cell/battery change substantially over temperature.

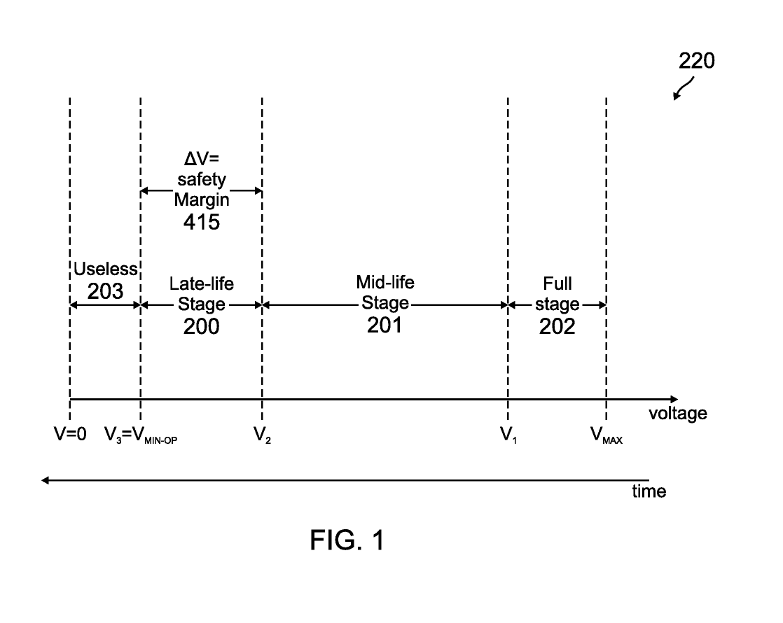

FIG. 1 shows exemplary life stages 200-203 of an exemplary life 220 of an electrochemical cell or battery in accordance with the present application. As a cell/battery powers a load, the charge of the cell/battery is depleted. As indicated by the time and voltage axes, the voltage across the cell/battery decreases with time unless the cell/battery is recharged. New cells/batteries have a higher voltage under load than cells/batteries in the late-life stage. The exemplary life stages 200-203 of the life 220 of an electrochemical cell or battery are shown as a function of voltage. A new cell/battery, which has not yet been used to power a load, is at V_{MAX}. For some cells/batteries, after a relatively short period of use, the voltage of the cell/battery is partially depleted to less than a voltage V₁. The cell/battery having a voltage between V_{MAX} and V₁ (V₁ is less than V_{MAX}) is considered to be in the full stage 202 in the life 220 of the cell/battery. As the cell/battery continues to power a load, the voltage of the cell/battery continues to decrease. The exemplary mid-life stage 201 in the exemplary life 220 of the cell/battery shown in FIG. 1 extends between V₂ and V₁, where V₂ is less than V₁. When the cell/battery is depleted to less than V₂ and greater than V₃, the cell/battery is in the late-life stage 200 in the life 220 of the cell/battery. The late-life stage 200 extends between V₂ and V₃, where V₃ is less than V₂. The difference between V₂ and V₃ (i.e., ΔV=V₂−V₃) equals a safety margin 415. When the voltage across the cell/battery is less than V₃, the cell/battery is considered to be in the useless or dead stage of life since the cell/battery is no longer able to power an exemplary load or component as required for the component to operate as desired. The voltage V₃ is also referred to herein as a minimum-operational voltage V_{MIN-OP}.

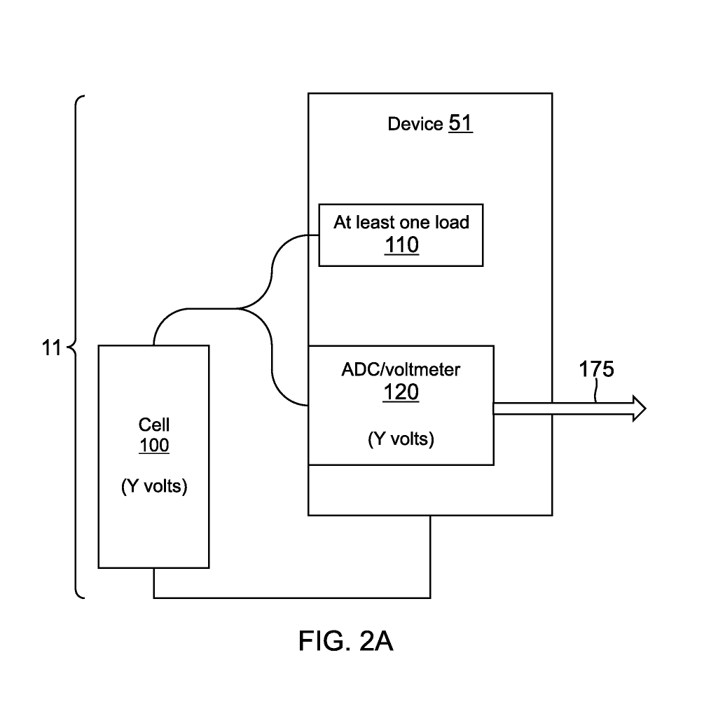

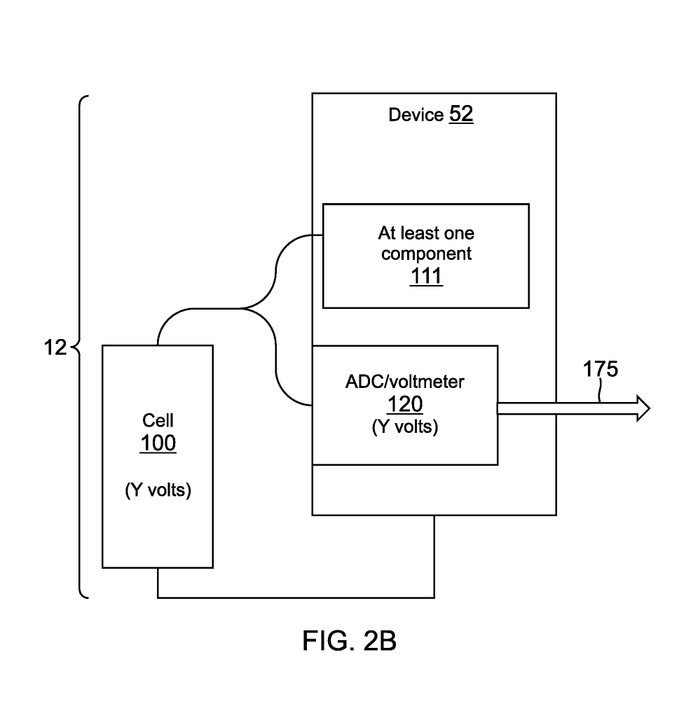

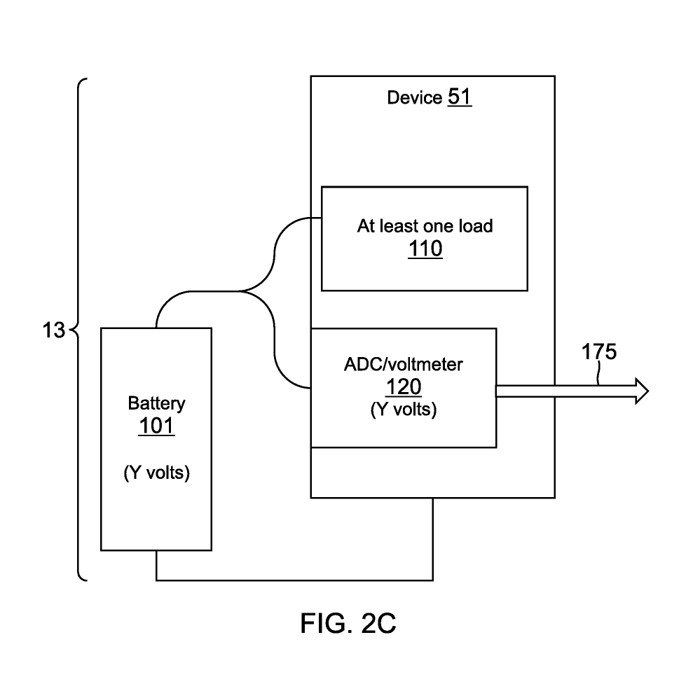

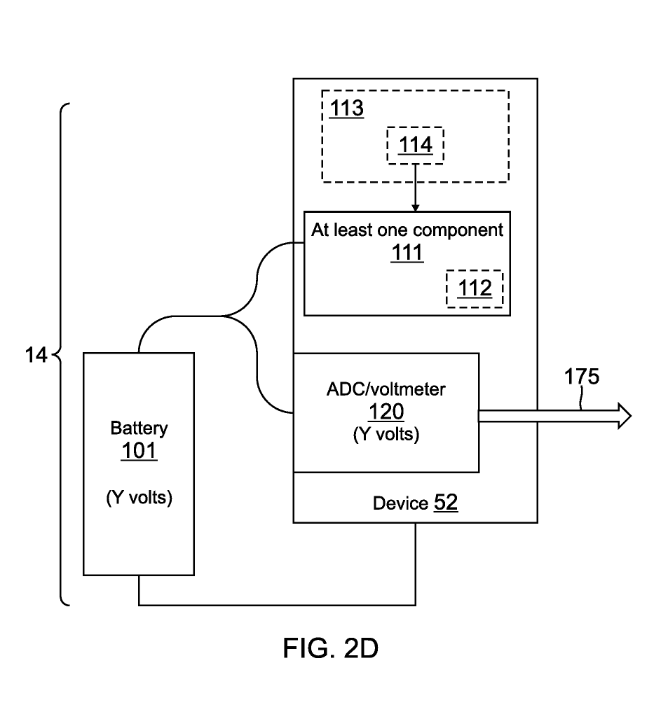

FIGS. 2A-2D show various embodiments of systems 11-14 to determine if an electrochemical cell/battery is in a late-life stage of the life of the electrochemical cell/battery in accordance with the present application.

As shown in FIG. 2A, system 11 includes a device 51 and an electrochemical cell 100. The device 51 includes at least one load 110 and an ADC/voltmeter 120. The electrochemical cell 100 in system 11 is configured to power the at least one load 110 while the ADC/voltmeter 120 is configured to measure the voltage (e.g. Y volts) across the electrochemical cell 100. The ADC/voltmeter 120 is referred to herein as a measuring component.

As shown in FIG. 2B, system 12 includes a device 52 and an electrochemical cell 100. The device 52 includes at least one component 111 and an ADC/voltmeter 120. The electrochemical cell 100 in system 12 is configured to power the at least one component 111 while the ADC/voltmeter 120 is configured to measure the voltage across the cell 100.

As shown in FIG. 2C, system 13 includes the device 51 and a battery 101. As in FIG. 2A, device 51 includes the at least one load 110 and the ADC/voltmeter 120. The battery 101 in system 13 is configured to power the at least one load 110 while the ADC/voltmeter 120 is configured to measure the voltage across the battery 101.

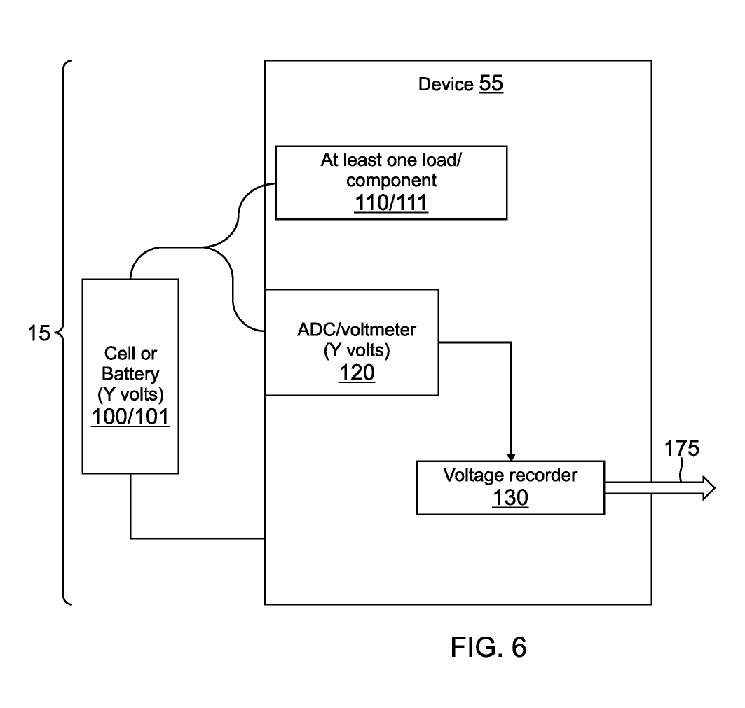

As shown in FIG. 2D, system 14 includes the device 52 and a battery 101. As in FIG. 2B, the device 52 includes the at least one component 111 and the ADC/voltmeter 120. The battery 101 in system 14 is configured to power the at least one component 111 while the ADC/voltmeter 120 is configured to measure the voltage across the battery 101. The exemplary device 52 in FIG. 2D includes an optional power supply circuit 113 that includes a regulator controller 114. The at least one component 111 in the exemplary device 52 in FIG. 2D also includes an optional logic chip 112. These optional power supply circuit 113, regulator controller 114 and logic chip 112 can also be in the device 52 shown in FIG. 2B and the devices described below with reference to FIGS. 6-11.

The load/component 110/111 is referred to herein as a powered load/component 110/111 since that is the component and/or load in the device 51/52 being powered by the cell/battery 100/101. The term “device 51/52” refers to either device 51 or device 52. The ADC/voltmeter 120 is referred to herein as a measuring component since it measures, at least once, a voltage of at least one electrochemical cell/battery 100/101 while the at least one electrochemical cell/battery 100/101 is powering at least one load/component 110/111. The ADC/voltmeter 120 can be an analog-to-digital converter, a voltmeter type of device, an operational amplifier, an analog comparator with variable voltage source for comparisons, an electrolyte level detector, a chemical sensor, a density sensor, or a charge level measurement detector. Other types of components to measure the voltage of the cell/battery 100/101 are possible.

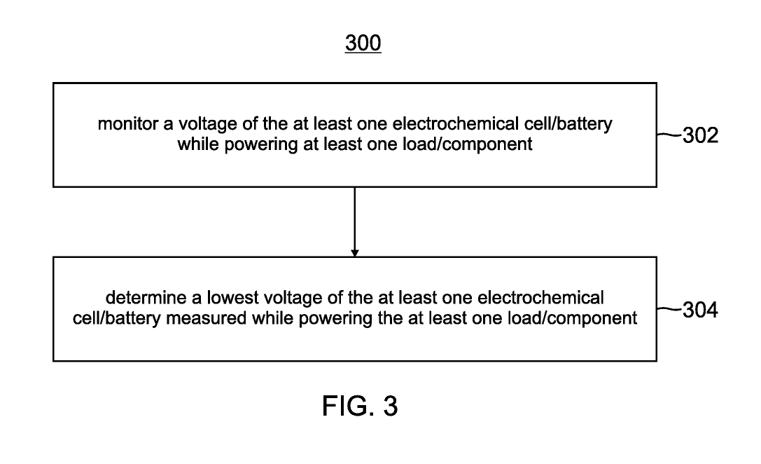

The operation of systems 11-14 of FIGS. 2A-2D is now described with reference to FIGS. 3, 4, and 5. FIG. 3 shows an embodiment of a method 300 to determine if an electrochemical cell/battery 100/101 is in a late-life stage 200 of the life of the electrochemical cell/battery 100/101 in accordance with the present application. At block 302, a voltage of the at least one electrochemical cell/battery 100/101 is measured while powering at least one load/component 110/111. The term load/component is used herein to refer to one of a load or a component. The term at least one load/component is used herein to refer to: at least one load; at least one component; and at least one of both a load and a component. In one implementation of this embodiment, the load is an element (e.g., a trace line or a resistive element) in a circuit.

At block 304, a lowest voltage of the at least one electrochemical cell/battery 100/101, which was measured while powering the at least one load/component 110/111, is determined. When the load or component draws current from the cell/battery 100/101, the voltage of the cell/battery 100/101 is monitored by the ADC/voltmeter 120 and the lowest voltage of the cell/battery 100/101 is determined over a period of time. In one implementation of this embodiment, the voltage of the cell/battery 100/101 is periodically measured by the ADC/voltmeter 120 over a preselected amount of time. The lowest voltage measured during this preselected amount of time is the lowest voltage. In this case, the ADC/voltmeter 120 continues to periodically measure the voltage of the cell/battery 100/101. When a second preselected amount of time has expired, the lowest voltage measured during this second preselected amount of time is the lowest voltage. The new lowest voltage can either replace the previous lowest voltage or be saved as a second lowest voltage. In one implementation of this embodiment, the lower of the new lowest voltage and the previous lowest voltage is selected to be the current lowest voltage.

The lowest measured voltage is used to determine the current life-stage in the life of the cell/battery 100/101.

The lowest voltage is used to determine if the cell/battery 100/101 is in the late-life stage 200. In one implementation of this embodiment, the ADC/voltmeter 120 determines if the lowest voltage is less than the minimum-voltage threshold Vₘᵢₙ₋ₜₕ, which is between V₂ and V₃ in FIG. 1. If the lowest voltage is below the minimum-voltage threshold Vₘᵢₙ₋ₜₕ, the device 51/52 outputs a warning indication 175 (FIG. 2A-2D). In another implementation of this embodiment, if the lowest voltage is below the voltage V₂ (i.e., is below V₃ plus the ΔV of the safety margin 415), the device 51/52 outputs a warning indication 175 (FIG. 2A-2D).

In this manner, a user of the cell/battery 100/101 is informed by the warning indication 175 that the cell/battery 100/101 is in a late-life stage 200 in the life of the cell/battery 100/101. The warning indication 175 reports that the cell/battery 100/101 is approaching the useless stage 203 in the life of the cell/battery 100/101 and should be replaced for the device 51/52 to continue to operate correctly. In one implementation of this embodiment, if the cell or battery is not in a late-life stage 200 (or dead stage 203) in the life of a cell or battery, a cell-OK indication 175 is output to report that the cell/battery 100/101 does not need to be replaced. In another implementation of this embodiment, the lowest (or minimum) voltage of the cell/battery 100/101 is recorded or stored.

The systems and method disclosed herein are inherently temperature compensated since the technique described herein measures the battery voltage. When the cell/battery becomes cold, the voltage reported (i.e., recorded or measured) decreases so voltage is a good indication of remaining cell/battery life of a cold cell/battery 100/101. At lower temperatures, the cell/battery 100/101 has less energy to deliver to the device 51/52 to be powered. At room temperature (normal) and higher temperatures, more life will be reported from the same cell/battery 100/101, since the cell/battery 100/101 has more energy to deliver to the device 51/52 to be powered at a normal or higher temperature.

By reporting full cell/battery life on a new cell/battery 100/101 that is adjusted for temperature, the system 11, 12, 13, or 14 reports a fully charged cell/battery 100/101 as being in the full stage 202 and reports a partially drained cell/battery 100/101 as being in mid-life stage 201 regardless of the temperature. The measured lowest voltage drops more quickly in time as the cell/battery 100/101 is reduced in temperature and the cell/battery 100/101 drains more quickly.

In another implementation of this embodiment, the system 11, 12, 13, or 14 is not compensated (i.e., the reported full cell/battery life on a new cell/battery 100/101 is not adjusted for temperature). Such a system relies on the inherent decline of the cell/battery 100/101 across temperature and adjusts reasonably for the required application.

There are a variety of ways to select the minimum-voltage threshold Vₘᵢₙ₋ₜₕ. In one implementation of this embodiment, the voltage is an arbitrarily selected voltage that is known to be relatively low with reference to the voltage in a new cell/battery 100/101. Setting an arbitrarily selected voltage as the minimum-voltage threshold Vₘᵢₙ₋ₜₕ is useful when the voltage is measured across a load 110 and is not measured across a component 111, since a load does not typically have a required minimum-powering voltage V_{min-power}.

The arbitrarily selected minimum-voltage threshold Vₘᵢₙ₋ₜₕ can be a selected percentage of V_{MAX} (FIG. 1). When the device 51/52 draws full operational current from the cell/battery 100/101, the voltage of the cell/battery 100/101 is monitored during this process, and the minimum voltage of the cell/battery 100/101 is recorded. This value is used to calculate a cell/battery-life percentage. A new cell/battery 100/101 reports a higher voltage under load. Mostly depleted cells/batteries 100/101 fall to much lower voltages. The voltage values for 100% and 0% are picked so that new cells/batteries 100/101 report (via warning indication 175) 100% and the brownout voltage of the device is reported as 0%. In this embodiment, as the cell/battery 100/101 loses its charge, the warning indication 175 reports lower and lower remaining life percentages.

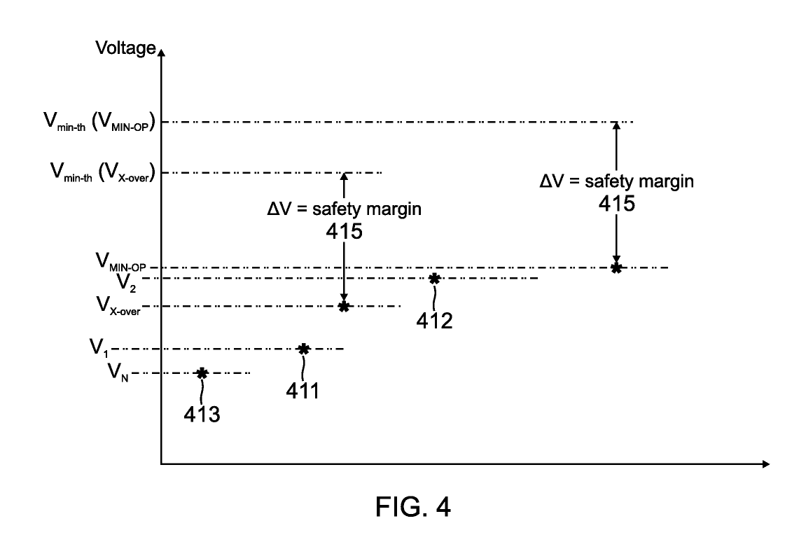

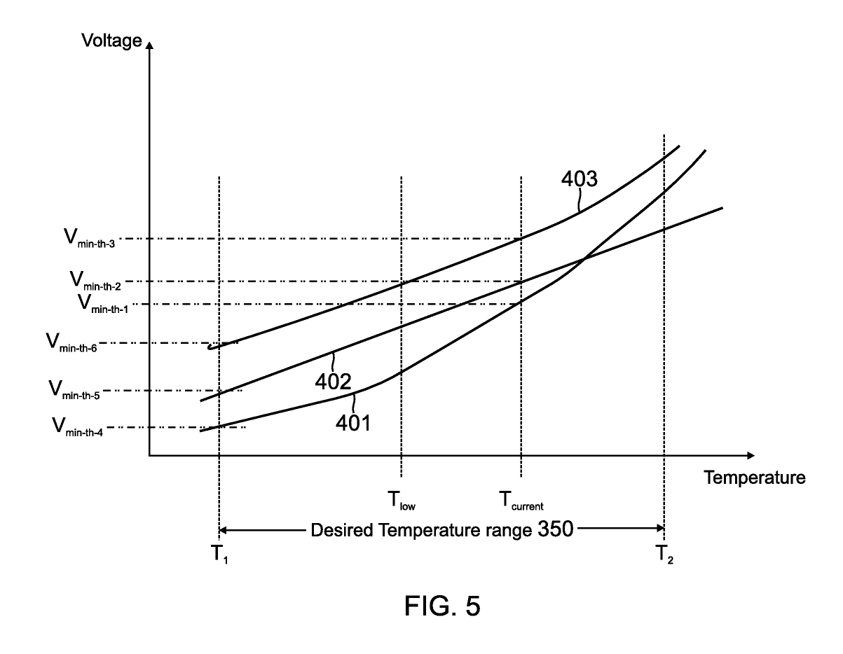

If the voltage is measured for a cell/battery 100/101 powering a plurality of components 111, the minimum-voltage threshold is based on minimum-powering voltage V_{min-power} required for the component 111 that uses the highest minimum voltage to operate. In this case, there are several techniques by which to select the minimum-voltage threshold Vₘᵢₙ₋ₜₕ as described with reference to FIGS. 4 and 5.

FIG. 4 shows a plurality of minimum-powering voltages V₁, V₂, and V_{N} for a respective plurality of components 111. The asterisks labeled as 411-413 indicate the N minimum-powering voltages for the N respective components in the device 52, where N is a positive integer. These values can be obtained from the specification sheets associated with the N components in the device 52. The minimum-powering voltage is also referred to as the “minimum-operating voltage (V_{MIN-OP})” or the “minimum-operational voltage (V_{MIN-OP})”.

In one implementation of this embodiment, the minimum-voltage threshold Vₘᵢₙ₋ₜₕ is selected by: 1) collecting at least one minimum-powering voltage V_{min-power} from a respective at least one datasheet associated with the at least one component 111; 2) selecting a crossover-threshold voltage Vₓ₋ₒᵥₑᵣ between proper operation and improper operation of the at least one component 111 or device 51/52; and 3) adding a safety margin 415 to the crossover threshold voltage to obtain the minimum-voltage threshold Vₘᵢₙ₋ₜₕ. This minimum-voltage threshold Vₘᵢₙ₋ₜₕ is a function of the crossover threshold voltage and is shown as minimum-voltage threshold Vₘᵢₙ₋ₜₕ (V_{X-over}) in FIG. 4.

The crossover-threshold voltage Vₓ₋ₒᵥₑᵣ is based on a consideration of the functional value of each of the N components 111. For example, if the function of a second component is not required for a key desired function of the device 52, the crossover-threshold voltage Vₓ₋ₒᵥₑᵣ can be lower than the minimum-powering voltage 412 at voltage V₂ for the second component as is shown in FIG. 4. If all of the N components 111 are critical to key functionality (i.e., desired functionality) of the device 52, the crossover-threshold voltage Vₓ₋ₒᵥₑᵣ is greater than the minimum-powering voltages V₁, V₂, and V_{N} for all of the N components 111. In this case, the crossover-threshold voltage Vₓ₋ₒᵥₑᵣ is equal to or slightly greater than the largest voltage V₂ of all the minimum-powering voltages V₁, V₂, and V_{N}. The crossover-threshold voltage Vₓ₋ₒᵥₑᵣ between proper operation and improper operation of the at least one component 111 or device 51/52 is selected by the device designer or one skilled in the art who reviews the minimum-powering voltages V₁, V₂, and V_{N} for N components 111 when designing the system to determine if an electrochemical cell is in a late-life stage of the life of at least one electrochemical cell.

In another implementation of this embodiment, the minimum-voltage threshold Vₘᵢₙ₋ₜₕ is selected by: 1) collecting at least one minimum-powering voltage V_{min-power} from a respective at least one datasheet associated with the at least one component 111; 2) selecting a crossover-threshold voltage Vₓ₋ₒᵥₑᵣ between proper operation and improper operation of the at least one component 111 or device 51/52; and 3) setting the crossover-threshold voltage Vₓ₋ₒᵥₑᵣ between proper operation and improper operation of the at least one component 111 or device 51/52 as the minimum-voltage threshold Vₘᵢₙ₋ₜₕ. In this embodiment, there is no added safety margin 415.

In yet another implementation of this embodiment, the minimum-voltage threshold Vₘᵢₙ₋ₜₕ is selected by: 1) collecting at least one minimum-powering voltage V_{min-power} from a respective at least one datasheet associated with the at least one component 111; 2) selecting a minimum operational voltage V_{MIN-OP} between proper operation and improper operation of the at least one component 111; and 3) adding a safety margin 415 to the minimum operational voltage V_{MIN-OP} to obtain the minimum-voltage threshold Vₘᵢₙ₋ₜₕ. This minimum-voltage threshold Vₘᵢₙ₋ₜₕ is shown as minimum-voltage threshold Vₘᵢₙ₋ₜₕ (V_{MIN-OP}) in FIG. 4.

In yet another implementation of this embodiment, the minimum-voltage threshold Vₘᵢₙ₋ₜₕ is selected by: 1) collecting at least one minimum-powering voltage V_{min-power} from a respective at least one datasheet associated with the at least one component 111; and 2) selecting the minimum operational voltage V_{MIN-OP} as the minimum-voltage threshold Vₘᵢₙ₋ₜₕ. This minimum-voltage threshold Vₘᵢₙ₋ₜₕ is shown as minimum-voltage threshold V_{MIN-OP} in FIG. 4. In this embodiment, there is no added safety margin 415.

If the device 51/52 is remotely located, it is desirable to have the safety margin 415 added to the minimum operational voltage V_{MIN-OP} or the crossover-threshold voltage Vₓ₋ₒᵥₑᵣ to ensure the device 51/52 remains operation while someone goes to the remote location to replace the cell/battery 100/101. If the device 51/52 is co-located with the user, the safety margin 415 does not necessarily need to be added to the minimum operational voltage V_{MIN-OP} or the crossover-threshold voltage Vₓ₋ₒᵥₑᵣ. In one implementation of this embodiment, the ΔV of the safety margin 415 for a co-located device 51/52 is lower than the ΔV of the safety margin 415 for a remotely located device 51/52.

FIG. 5 shows a plurality of plots 401, 402, and 403 of minimum-powering voltages as a function of temperature for a respective plurality of components in the device 51/52 over a desired temperature range 350. The desired temperature range 350 is that range of temperatures that the device 51/52 may experience while in operation. As shown in FIG. 5, the desired temperature range 350 extends from the low temperature of T₁ to the high temperature of T₂. The plots 401, 402, and 403 of minimum-powering voltages as a function of temperature for each of the components 111 in the device 52 are obtained from spec sheets associated with the components 111.

The minimum-powering voltages as a function of temperature for a first component 111 is shown as plot 401. The minimum-powering voltages as a function of temperature for a second component 111 is shown as plot 402. The minimum-powering voltages as a function of temperature for a third component 111 is shown as plot 403.

In one implementation of this embodiment, the minimum-voltage threshold Vₘᵢₙ₋ₜₕ is selected by: 1) providing at least one plot 401-403 of minimum-voltage thresholds Vₘᵢₙ₋ₜₕ as a function of temperature for the respective at least one component 111; and 2) selecting the minimum-voltage threshold Vₘᵢₙ₋ₜₕ based on a current temperature T_{curr} of one of: at least one of the at least one electrochemical cell 100; the device 51/52; and the at least one component 111. As shown in FIG. 5, at the current temperature T_{curr} the plots 401-403 each intersect the voltage axis as three points indicated as Vₘᵢₙ₋ₜₕ₋₁, Vₘᵢₙ₋ₜₕ₋₂, and Vₘᵢₙ₋ₜₕ₋₃. Since Vₘᵢₙ₋ₜₕ₋₃ is greater than both Vₘᵢₙ₋ₜₕ₋₁ and Vₘᵢₙ₋ₜₕ₋₂, the minimum-voltage threshold Vₘᵢₙ₋ₜₕ is selected to be Vₘᵢₙ₋ₜₕ₋₃. In another implementation of this embodiment, the minimum-voltage threshold Vₘᵢₙ₋ₜₕ is selected to be Vₘᵢₙ₋ₜₕ₋₃ plus ΔV to include the safety margin 415. The temperature of at least one of: at least one of the at least one electrochemical cell/battery 100/101; at least one of the at least one load/component 110/111; and the device 51/52 is measured at least once after the device 51/52 is powered up. In one implementation of this embodiment, the temperature of at least one of: at least one of the at least one electrochemical cell/battery 100/101; at least one of the at least one load/component 110/111; and the device 51/52 is periodically measured.

In yet another implementation of this embodiment, the minimum-voltage threshold Vₘᵢₙ₋ₜₕ is selected by: 1) providing at least one plot 401-403 of minimum-voltage thresholds Vₘᵢₙ₋ₜₕ as a function of temperature for the respective at least one component 111; and 2) selecting the minimum-voltage threshold Vₘᵢₙ₋ₜₕ to be the voltage requirement for the component that has the highest voltage requirement at the lowest desired operational temperature T₁. As shown in FIG. 5, at the lowest desired operational temperature T₁, the plots 401-403 each intersect the voltage axis as three points indicated as Vₘᵢₙ₋ₜₕ₋₄, Vₘᵢₙ₋ₜₕ₋₅, and Vₘᵢₙ₋ₜₕ₋₆. Since Vₘᵢₙ₋ₜₕ₋₆ is greater than both Vₘᵢₙ₋ₜₕ₋₅ and Vₘᵢₙ₋ₜₕ₋₄, the minimum-voltage threshold Vₘᵢₙ₋ₜₕ is selected to be Vₘᵢₙ₋ₜₕ₋₆. In another implementation of this embodiment, the minimum-voltage threshold Vₘᵢₙ₋ₜₕ is selected to be Vₘᵢₙ₋ₜₕ₋₆ plus ΔV to include the safety margin 415. In this manner, the minimum-voltage threshold Vₘᵢₙ₋ₜₕ is selected to match or exceed the voltage, below which a circuit in the at least one component 111 is incapable of powering according to an intended and desired function across a desired temperature range. As described above a safety margin 415 is added or not based on the location of the device with respect to the user of the device 52.

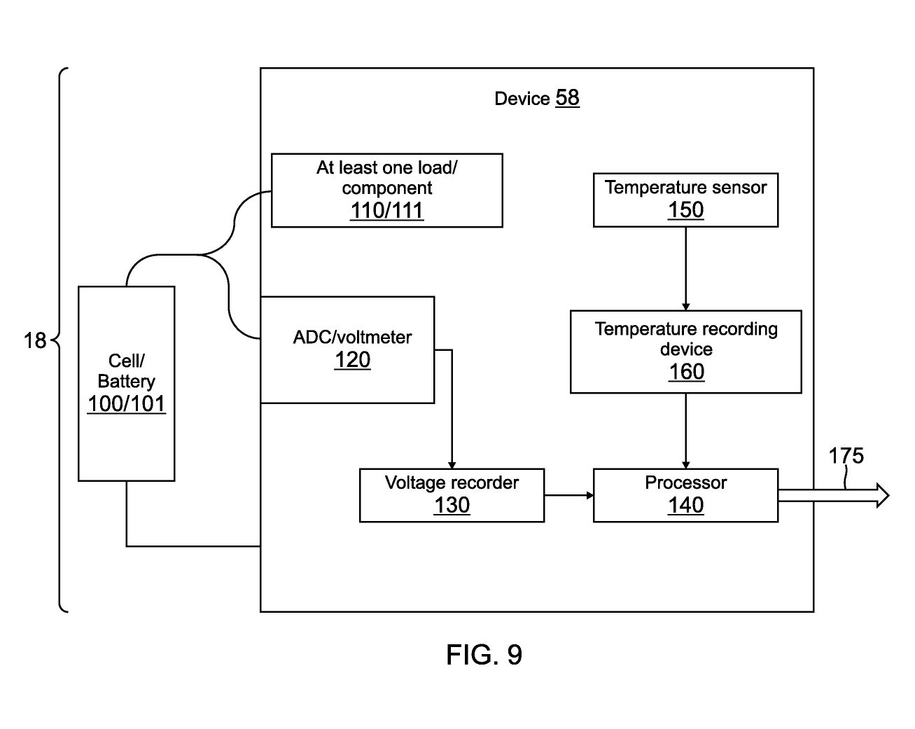

FIG. 5 also shows a lowest temperature T_{low} that intersects the plots 401-403. The use of lowest temperature T_{low} is described below with reference to FIG. 9.

In one implementation of this embodiment, a minimum-voltage threshold Vₘᵢₙ₋ₜₕ is selected to match or exceed a minimum-powering voltage V_{min-power} of a logic chip 112 used in the at least one component 111. In another implementation of this embodiment, a minimum-voltage threshold Vₘᵢₙ₋ₜₕ is selected to match or exceed a minimum-powering voltage V_{min-power} of a regulator controller 114 for a power supply circuit 113 that powers the at least one component 111. In yet another implementation of this embodiment, the minimum-voltage threshold Vₘᵢₙ₋ₜₕ of the at least one component 111 is selected with a selected safety margin 415 above a minimum-operational voltage specified to avoid circuit malfunctions in the device 52.

In one implementation of this embodiment, the ADC/voltmeter 120 is a measuring and processing component that determines a lowest voltage of the at least one electrochemical cell/battery 100/101 measured while powering the at least one load/component 110/111, and outputs a warning indication 175 based on a determination that the lowest voltage is below the minimum-voltage threshold. In another implementation of this embodiment, the ADC/voltmeter 120 is a measuring component to measure voltages and other components are used to process the measured voltages as described below.

In one implementation of this embodiment of method 300, a maximum-voltage value and a minimum-voltage value are selected for a desired voltage range of the at least one electrochemical cell or the at least one battery. The desired voltage range of the at least one electrochemical cell or at least one battery is between the maximum-voltage value and the minimum-voltage value. In one implementation of this embodiment, the maximum-voltage value is approximately V_{MAX} (FIG. 1) and the minimum-voltage value is approximately V_{MIN-OP} (see FIG. 1). The minimum-voltage value can be one of several values selected in the same manner that the minimum-voltage thresholds Vₘᵢₙ₋ₜₕ are selected as described herein.

The lowest voltage of at least one of the electrochemical cell/battery that is determined (e.g., measured) while powering the at least one load is collected. In one implementation of this embodiment, a plurality of lowest voltages are periodically measured while powering the at least one load and the respective plurality of lowest voltages are collected.

A remaining life value is calculated based on the selected maximum-voltage value, the minimum-voltage value and the collected lowest voltage. For example, the remaining life value can be a percentage of the collected lowest voltage within the desired voltage range over the minimum-voltage value. Then the calculated remaining life value is output.

In one implementation of this embodiment, remaining life value is output as a number of hours remaining before the cell/battery is useless. In another implementation of this embodiment, the remaining life value is output as a number of hours remaining before the cell/battery should be replaced. In yet another implementation of this embodiment, remaining life value is output as a percentage of the collected lowest voltage within the desired voltage range over the minimum-voltage value.

FIGS. 6-11 show various embodiments of systems 15-20 to determine if an electrochemical cell/battery 100/101 is in a late-life stage 200 of the life 220 of the respective electrochemical cell/battery 100/101 in accordance with the present application.

As shown in FIG. 6, system 15 includes a device 55 and an electrochemical cell/battery 100/101. The device 55 includes at least one load 110 and an ADC/voltmeter 120 and a voltage recorder 130. The at least one load 110 and an ADC/voltmeter 120 have the structure and function as described above with reference to FIGS. 2A-2D. The electrochemical cell/battery 100/101 in system 15 is configured to power the at least one load/component 110/111 while the ADC/voltmeter 120 is configured to measure the voltage across the electrochemical cell/battery 100/101. The ADC/voltmeter 120 outputs the measured voltage to the voltage recorder 130. The voltage recorder 130 records the measured at least one voltage and is also referred to herein as a processing component. In one implementation of this embodiment, the voltage recorder 130 determines the lowest voltage of the electrochemical cell/battery 100/101 measured while powering the at least one load/component 110/111, and outputs a warning indication 175 if it is determined the lowest voltage is below the minimum-voltage threshold Vₘᵢₙ₋ₜₕ.

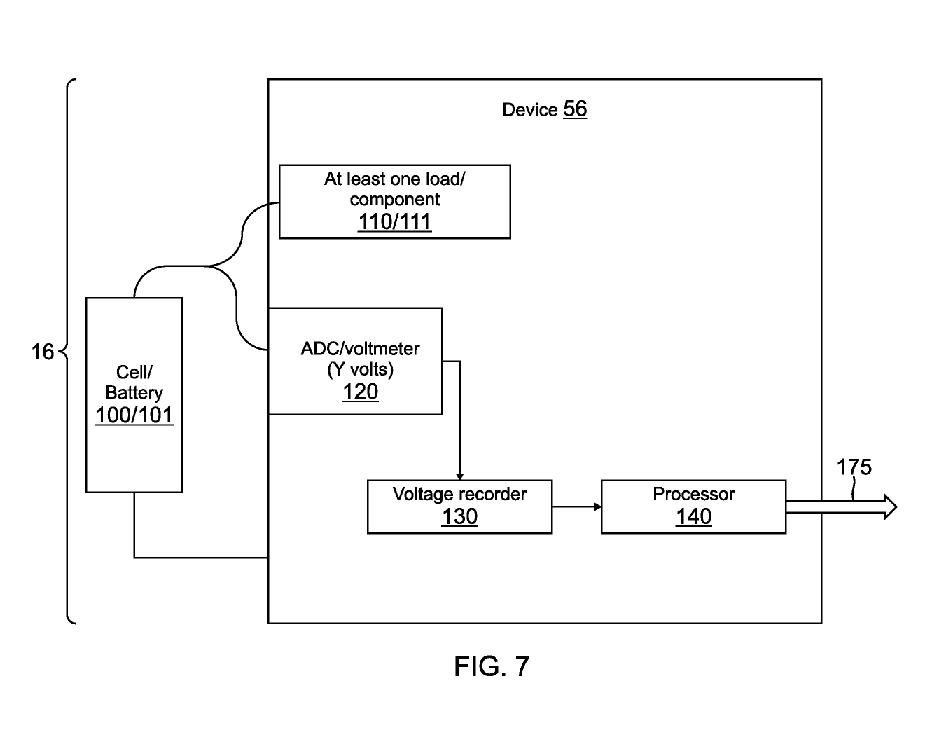

The system 16 of FIG. 7 differs from the system 15 of FIG. 6 in that a processor 140 is included in the device 56. As shown in FIG. 7, system 16 includes a device 56 and an electrochemical cell/battery 100/101. The device 56 includes at least one load/component 110/111, an ADC/voltmeter 120, a voltage recorder 130, and the processor 140. The electrochemical cell/battery 100/101 in system 16 is configured to power the at least one load/component 110/111 while the ADC/voltmeter 120 is configured to measure the voltage across the electrochemical cell/battery 100/101. The voltage recorder 130 records the measured at least one voltage and sends at least one of the measured voltages to the processor 140. The processor 140 determines the lowest voltage of the at least one electrochemical cell/battery 100/101 measured while powering the at least one load/component 110/111. The processor 140 outputs a warning indication 175 if it is determined the lowest voltage is below the minimum-voltage threshold Vₘᵢₙ₋ₜₕ. The voltage recorder 130 and the processor 140 are also referred to herein as processing components.

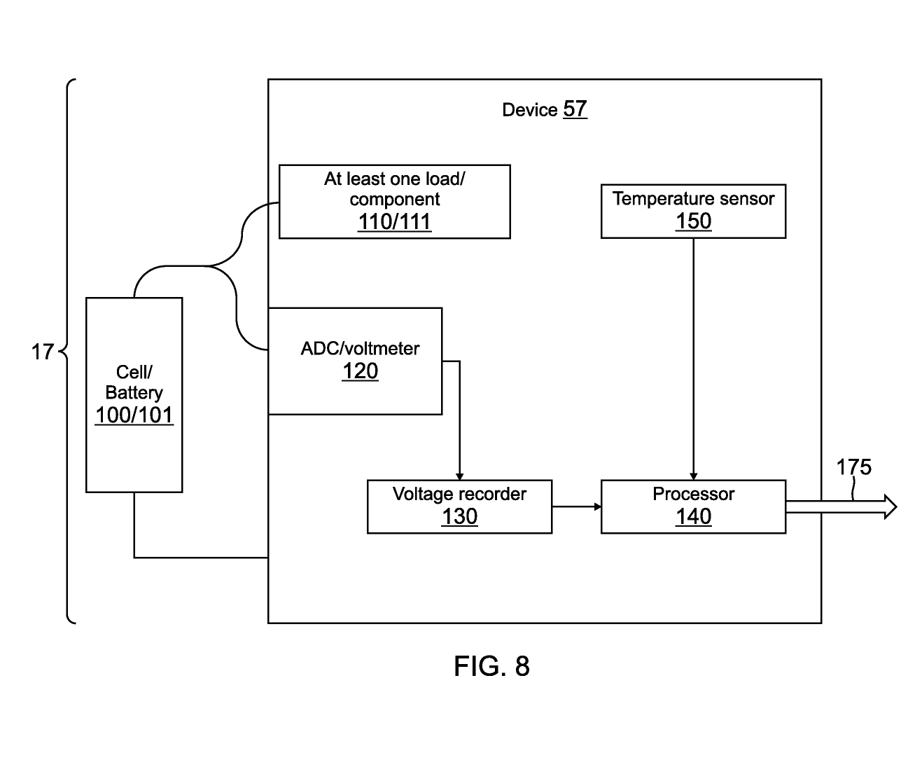

The system 17 of FIG. 8 differs from the system 16 of FIG. 7 in that a temperature sensor 150 is included in the device 57. As shown in FIG. 8, system 17 includes the device 57 and an electrochemical cell/battery 100/101. The device 57 includes at least one load/component 110/111, the ADC/voltmeter 120, the voltage recorder 130, the processor 140, and the temperature sensor 150. The electrochemical cell/battery 100/101 in system 17 is configured to power the at least one load/component 110/111 while the ADC/voltmeter 120 is configured to measure the voltage across the electrochemical cell/battery 100/101. The voltage recorder 130 records the measured at least one voltage and sends at least one of the measured voltages to the processor 140. The temperature sensor 150 measures the temperature of at least one of: the cell/battery 100/101; at least one of the at least one load/component 110/111; and the device 57.

The temperature sensor 150 outputs temperature data to the processor 140. In one implementation of this embodiment, the temperature sensor 150 periodically outputs the sensed temperature data to the processor 140. In another implementation of this embodiment, temperature sensor 150 outputs the sensed temperature data to the processor 140 after when the device 57 is powered up. The processor 140 inputs the temperature data from the temperature sensor 150 and determines the minimum-voltage threshold Vₘᵢₙ₋ₜₕ based on the current temperature T_{curr}. The processor 140 also determines the lowest voltage of the at least one electrochemical cell/battery 100/101 measured while powering the at least one load/component 110/111. The processor 140 outputs a warning indication 175 if it is determined the lowest voltage is below the minimum-voltage threshold Vₘᵢₙ₋ₜₕ based on the current temperature T_{curr}.

The system 18 of FIG. 9 differs from the system 17 of FIG. 8 in that a temperature recording device 160 is included in the device 58. As shown in FIG. 9, system 18 includes the device 58 and an electrochemical cell/battery 100/101. The device 58 includes at least one load/component 110/111, the ADC/voltmeter 120, the voltage recorder 130, the processor 140, the temperature sensor 150, and the temperature recording device 160. The electrochemical cell/battery 100/101 in system 18 is configured to power the at least one load/component 110/111 while the ADC/voltmeter 120 is configured to measure the voltage across the electrochemical cell/battery 100/101. The voltage recorder 130 records the measured at least one voltage and sends the at least one measured voltages to the processor 140.

The temperature sensor 150 measures the temperature of at least one of: the cell/battery 100/101; at least one of the at least one load/component 110/111; and the device 58. The temperature sensor 150 periodically outputs the measured temperature data to the temperature recording device 160. The temperature recording device 160 inputs the temperature data from the temperature sensor 150 and records the measured temperatures. The temperature recording devices outputs the lowest temperature T_{low} to the processor 140. The processor 140 inputs the temperature data from the temperature recording device 160 and determines the minimum-voltage threshold Vₘᵢₙ₋ₜₕ based on the lowest temperature T_{low} (FIG. 5). The plots 401-403 shown in FIG. 5 intersect the lowest temperature T_{low} at three voltages. In one implementation of this embodiment, the highest of these voltages is the minimum-voltage threshold Vₘᵢₙ₋ₜₕ. In another implementation of this embodiment, the highest of these voltages plus ΔV (to include the safety margin 415) is the minimum-voltage threshold Vₘᵢₙ₋ₜₕ.

The processor 140 also determines the lowest voltage of the at least one electrochemical cell/battery 100/101 measured while powering the at least one load/component 110/111. The processor 140 outputs a warning indication 175 if it is determined the lowest voltage is below the minimum-voltage threshold Vₘᵢₙ₋ₜₕ based on the lowest temperature T_{low}.

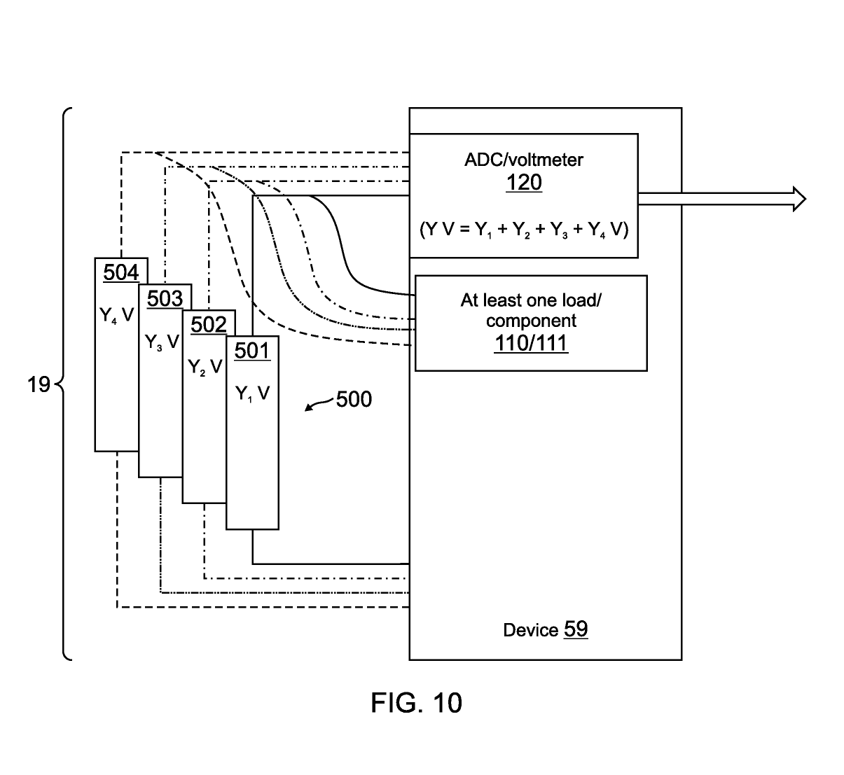

As shown in FIG. 10, system 19 includes a device 59 and a plurality of electrochemical cells/batteries 501-504. The device 59 includes at least one load/component 110/111 and an ADC/voltmeter 120. The load/component 110/111 is powered by one or more of the cells/batteries 501-504 at any given time. The ADC/voltmeter 120 is configured to measure the voltage across the electrochemical cells/batteries 501-504 that are powering the load/component 110/111. The voltage recorder 130 outputs a warning indication 175 if it is determined the lowest voltage is below the minimum-voltage threshold Vₘᵢₙ₋ₜₕ. In another implementation of this embodiment, the device 59 includes one or more of the voltage recorder 130, the processor 140, the temperature sensor 150, and the temperature recording device 160 as shown in device 58 of FIG. 9.

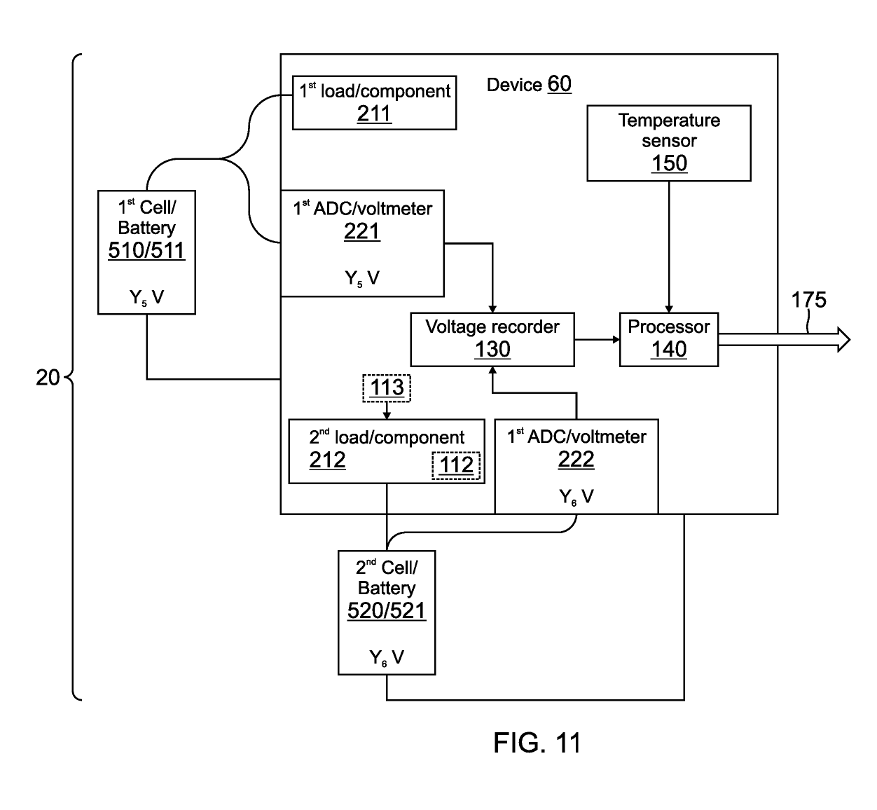

As shown in FIG. 11, system 20 includes a device 60, a first cell/battery 510/511, and a second cell/battery 520/521. The device 60 includes a first load/component 211, a second load/component 212, a first ADC/voltmeter 221, a second ADC/voltmeter 222, a voltage recorder 130, a processor 140, and a temperature sensor 150. In one implementation of this embodiment, the device 60 also includes the temperature recording device 160 as shown in device 58 of FIG. 9.

The first cell/battery 510/511 is configured to power the first load/component 211 while the first ADC/voltmeter 221 is configured to measure the voltage across the first cell/battery 510/511. The second cell/battery 520/521 is configured to power the second load/component 212 while the second ADC/voltmeter 222 is configured to measure the voltage across the second cell/battery 520/521. The first ADC/voltmeter 221 and the second ADC/voltmeter 222 each output the measured voltage to the voltage recorder 130. The voltage recorder 130 separately records the measured at least one voltage for the first load/component 211 and the second load/component 212. In one implementation of this embodiment, the first ADC/voltmeter 221 and the second ADC/voltmeter 222 periodically output the measured voltage to the voltage recorder 130 while the respective first load/component 211 and the second load/component 212 are powered by the respective first cell/battery 510/511 and second cell/battery 520/521. When the first load/component 211 or the second load/component 212 are not being powered by the respective first cell/battery 510/511 or second cell/battery 520/521, the respective first ADC/voltmeter 221 or the second ADC/voltmeter 222 does not send any voltage measurements to the voltage recorder 130.

The temperature sensor 150 measures the temperature of at least one of: the first load/component 211; the second load/component 212; the first cell/battery 510/511; the second cell/battery 520/521; and the device 60. In one implementation of this embodiment, temperature sensor 150 periodically measures the temperature of at least one of: the first load/component 211; the second load/component 212; the first cell/battery 510/511; the second cell/battery 520/521; and the device 60. In another implementation of this embodiment, temperature sensor 150 measures the temperature of at least one of: the first load/component 211; the second load/component 212; the first cell/battery 510/511; the second cell/battery 520/521; and the device 60 after either the first load/component 211 or the second load/component 212 is powered one.

The processor 140 determines the lowest voltage of the first cell/battery 510/511 measured while powering the first load/component 211. The processor 140 outputs a warning indication 175 for the first cell/battery 510/511 if it is determined the lowest voltage for the first cell/battery 510/511 is below the minimum-voltage threshold Vₘᵢₙ₋ₜₕ. The processor 140 also determines the lowest voltage of the second cell/battery 520/521 measured while powering the first load/component 212. The processor 140 outputs a warning indication 175 for the second cell/battery 520/521 if it is determined the lowest voltage for the second cell/battery 520/521 is below the minimum-voltage threshold Vₘᵢₙ₋ₜₕ. The minimum-voltage threshold Vₘᵢₙ₋ₜₕ is determined using the techniques described herein.

The systems described herein include temperature compensation. Batteries in lower temperatures typically have less battery capacity and so the remaining life calculation automatically reports lower values. Temperature compensation adjusts the battery life reporting so that new batteries report as new regardless of the temperature. For mostly depleted batteries in cold temperatures, if the voltage reaches the useless life stage 203 (or voltage at or below Vₘᵢₙ₋ₒₚ), the device reports useless life stage 203. A device remaining in this cold temperature requires a new battery. If the temperature increases, the device indicates a higher remaining battery capacity, and this same battery will last longer if the higher temperature is maintained. Thus, the systems described herein adjust the reports for reasonable remaining battery capacity as the temperature changes.

The methods and systems described herein have many advantages over the prior art systems. The systems described here can be used with batteries that have a flat voltage profile across discharge. The remaining battery life of batteries powering devices is measured without using expensive battery modules that require custom enclosures and smart battery circuitry. The remaining cell/battery life can be measured with a simple analog-to-digital converter (ADC) available in most embedded processor chips. The battery measurement is reasonable across the lifetime of the battery, even if batteries are exchanged between devices, or stored on a shelf for an unknown time and is reasonable across temperature. Operators are informed of or have the required information to predict when a device requires battery recharge or replacement. Smart battery modules are not necessary. Coulomb counter circuits are not necessary. If one cell/battery is exchanged for another cell/battery, the cell/battery life prediction is still valid. Simple cells or batteries can be used. The device still reports reasonable battery life values across temperature.

In one implementation of the systems described herein, a processor is not in the system. In another implementation of the methods and systems described herein, processing components (e.g., voltage recorder 130, processor 140), the temperature sensor 150, and/or the temperature recording device 160 include, or function with, software programs, firmware, or other processor readable instructions for carrying out the various functions used to determine if at least one electrochemical cell is in a late-life stage of the at least one electrochemical cell. In one implementation, the processing components include a microprocessor or microcontroller. In another implementation, the processing components include one or more of an op-amp circuit, an analog circuit with thresholds, and/or an analog to digital circuit with hardwired trip points. In yet another implementation, the processing components include processor support chips and/or system support chips such as application-specific integrated circuits (ASICs) and field-programmable gate arrays (FPGAs).

### Example Embodiments

Example 1 includes a method to determine if at least one electrochemical cell is in a late-life stage of a life of the at least one electrochemical cell, the method comprising: monitoring a voltage of the at least one electrochemical cell while powering at least one load; and determining a lowest voltage of the at least one electrochemical cell measured while powering the at least one load.

Example 2 includes the method of Example 1, further comprising: determining at least one of the at least one electrochemical cell is in the late-life stage based on the lowest voltage.

Example 3 includes the method of any of Examples 1-2, further comprising: determining the lowest voltage of at least one of the at least one electrochemical cell measured while powering the at least one load is at or below a minimum-voltage threshold; and outputting a warning indication based on the determination that the lowest voltage is below the minimum-voltage threshold.

Example 4 includes the method of any of Examples 1-3, wherein monitoring the voltage of the at least one electrochemical cell while powering the at least one load comprises: monitoring the voltage of the at least one electrochemical cell while powering at least one component in a device, the method further comprising: providing at least one plot of minimum-powering voltages as a function of temperature for the respective at least one component; and selecting the minimum-voltage threshold based on a current temperature of one of: at least one of the at least one electrochemical cell; the device; and the at least one component.

Example 5 includes the method of any of Examples 1-4, wherein monitoring the voltage of the at least one electrochemical cell while powering the at least one load comprises: monitoring the voltage of the at least one electrochemical cell while powering at least one component in a device, the method further comprising: collecting at least one minimum-powering voltage from a respective at least one datasheet associated with the at least one component; selecting a crossover-threshold voltage between proper operation and improper operation of the at least one component; and adding a safety margin to the crossover threshold voltage to obtain the minimum-voltage threshold.

Example 6 includes the method of any of Examples 1-5, wherein monitoring the voltage of the at least one electrochemical cell while powering the at least one load comprises: monitoring the voltage of the at least one electrochemical cell while powering at least one component in a device, the method further comprising: indicating at least one of the at least one electrochemical cell is in a late-life stage when one of the lowest voltages is within a safety margin of a minimum-voltage threshold of the at least one component in the device.

Example 7 includes the method of Example 6, the method further comprising: selecting the minimum-voltage threshold to match a minimum-powering voltage of a logic chip used in the at least one component.

Example 8 includes the method of any of Examples 6-7, the method further comprising: selecting the minimum-voltage threshold to match a minimum-powering voltage of a regulator controller for a power supply circuit that powers the at least one component.

Example 9 includes the method of any of Examples 6-8, the method further comprising: selecting the minimum-voltage threshold of the at least one component with a selected safety margin above a minimum-powering voltage specified to avoid circuit malfunctions.

Example 10 includes the method of any of Examples 6-9, the method further comprising: selecting the minimum-voltage threshold below which a circuit in the at least one component is incapable of powering according to an intended function across a desired temperature range.

Example 11 includes the method of any of Examples 1-10, wherein monitoring the voltage of the at least one electrochemical cell while powering the at least one load comprises: monitoring the voltage of the at least one electrochemical cell while powering at least one component in a device, the method further comprising: measuring a temperature of at least one of: at least one of the at least one electrochemical cell; at least one of the at least one component; and the device; and determining at least one of the at least one electrochemical cell is in the late-life stage based on a current temperature of the at least one of: the at least one of the at least one electrochemical cell; the at least one of the at least one component; and the device.

Example 12 includes the method of any of Examples 1-11, wherein monitoring the voltage of the at least one electrochemical cell while powering the at least one load comprises: monitoring the voltage of the at least one electrochemical cell while powering at least one component in a device, the method further comprising: periodically measuring a temperature of at least one of: at least one of the at least one electrochemical cell; at least one of the at least one component; and the device; recording the periodically measured temperatures; and determining at least one of the at least one electrochemical cell is in the late-life stage based on the recording of the measured temperatures of the at least one of: the at least one of the at least one electrochemical cell; the at least one of the at least one component; and the device.

Example 13 includes the method of any of Examples 1-12, further comprising: determining the lowest voltage of at least one of the at least one electrochemical cell measured, while powering the at least one load, is above a minimum-voltage threshold; and outputting a cell-OK indication based on the determination that the lowest voltage is above the minimum-voltage threshold.

Example 14 includes the method of any of Examples 1-13, wherein the at least one electrochemical cell comprises at least one battery, wherein monitoring the voltage of the at least one electrochemical cell while powering the at least one load comprises: periodically measuring a voltage of the at least one battery while powering the at least one component.

Example 15 includes the method of any of Examples 1-14, wherein monitoring the voltage of the at least one electrochemical cell while powering the at least one load comprises: monitoring the voltage of the at least one electrochemical cell while powering at least one component in a device, the method further comprising: measuring a temperature of the device at a temperature sensor; inputting information indicative of the measured temperature of the device to a processor.

Example 16 includes the method of any of Examples 1-15, further comprising: selecting a maximum-voltage value and a minimum-voltage value for a desired voltage range of the at least one electrochemical cell, wherein monitoring the voltage of the at least one electrochemical cell while powering the at least one load comprises: collecting the lowest voltage of at least one of the at least one electrochemical cell determined while powering the at least one load, the method further comprising: calculating a remaining life value based on the selected maximum-voltage value, the minimum-voltage value and the determined lowest voltage; and outputting the remaining life value.

Example 17 includes a system to determine if at least one electrochemical cell is in a late-life stage of a life of the at least one electrochemical cell, the method comprising: at least one measuring component to measure a voltage of at least one electrochemical cell while the at least one electrochemical cell is powering at least one load; and at least one processing component to record the measured at least one voltage, to determine a lowest voltage of the at least one electrochemical cell measured while powering the at least one load, and to output a warning indication based on a determination that the lowest voltage is below a minimum-voltage threshold.

Example 18 includes the system of Example 17, wherein the at least one processing component comprises: a voltage recorder to record the measured at least one voltage and output the voltage; and a processor to input the measured voltage from the voltage recorder, to determine the lowest voltage of the at least one electrochemical cell measured while powering the at least one load, and to output the warning indication based on the determination that the lowest voltage is below the minimum-voltage threshold.

Example 19 includes the system of any of Examples 17-18, wherein the at least one load is at least one powered component, the system further comprising: a temperature sensor to measure a temperature of at least one of: the electrochemical cell; and the at least one component powered by the at least one electrochemical cell.

Example 20 includes the system of any of Examples 17-19, wherein the at least one load is at least one component, the system further comprising: a temperature sensor to periodically measure a temperature of at least one of: the electrochemical cell; and the at least one component powered by the at least one electrochemical cell; and a temperature recording device to input and record the measured temperatures and to output a lowest temperature to the processor.

Example 21 includes the system of any of Examples 17-20, wherein the at least one processing component comprises: a voltage recorder to determine the lowest voltage of the at least one electrochemical cell measured while powering the at least one load, and to output the warning indication based on the determination that the lowest voltage is below the minimum-voltage threshold.

Example 22 includes a method to determine if at least one battery is in a late-life stage of the at least one battery, the method comprising: monitoring a voltage of the at least one battery while powering at least one component; determining a lowest voltage of the at least one battery measured while powering the at least one component; and determining at least one of the at least one battery is in the late-life stage based on the lowest voltage.

Example 23 includes the method of Example 22, further comprising: outputting a warning indication based on the determination that the lowest voltage is below a minimum-voltage threshold.

Example 24 includes the method of any of Examples 22-23, the method further comprising: selecting a minimum-voltage threshold, wherein the selecting comprises one of: selecting the minimum-voltage threshold to match a minimum-powering voltage of a logic chip used in the at least one component; selecting the minimum-voltage threshold of a regulator controller for a power supply circuit that powers the at least one component; selecting the minimum-voltage threshold of the at least one component to include a safety margin above a minimum-operational voltage specified to avoid circuit malfunctions in the at least one component; selecting the minimum-voltage threshold above a minimum-operational voltage specified to permit a circuit to provide a desired function across a desired temperature range.

Example 25 includes the method of any of Examples 22-24, wherein monitoring the voltage of the at least one electrochemical cell while powering the at least one load comprises: monitoring the voltage of the at least one electrochemical cell while powering at least one component in a device, the method further comprising: providing plots of minimum-powering voltages as a function of temperature; and selecting a minimum-voltage threshold based on a current temperature of one of: at least one of the at least one electrochemical cell; the device; and the at least one component.

Example 26 includes the method of any of Examples 22-25, further comprising: collecting minimum-powering voltages from at least one datasheet associated with the at least one component; selecting a crossover-threshold voltage between proper operation and improper operation of the at least one component; and adding a safety margin to the crossover threshold voltage to obtain a minimum-voltage threshold.

Example 27 includes the method of any of Examples 22-26, wherein monitoring the voltage of the at least one battery while powering the at least one component comprises: monitoring the voltage of the at least one battery while powering at least one component in a device, the method further comprising: indicating at least one of the at least one battery is in the late-life stage when one of the lowest voltages approaches the voltage requirements of the at least one component in the device.

Example 28 includes the method of any of Examples 22-27, the method further comprising: measuring a temperature of at least one of: at at least one of the at least one battery; at least one of the at least one component; and the device; and determining at least one of the at least one battery is in the late-life stage based on a current temperature of at least one of: the at least one of the at least one electrochemical cell; the at least one of the at least one component; and the device.

Example 29 includes the method of any of Examples 22-28, further comprising: selecting a maximum-voltage value and a minimum-voltage value for a desired voltage range of the at least one battery, wherein monitoring a voltage of the at least one battery while powering at least one component comprise: collecting the lowest voltage of at least one of the at least one battery determined while powering the at least one component, the method further comprising: calculating a remaining life value based on the selected maximum-voltage value, the minimum-voltage value and the collected lowest voltage; and outputting the remaining life value.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A method to determine if at least one electrochemical cell is in a late-life stage of a life of the at least one electrochemical cell, the method comprising:
monitoring a voltage of the at least one electrochemical cell while powering at least one load; and
determining a lowest voltage of the at least one electrochemical cell measured while powering the at least one load.

2. The method of claim 1, further comprising:
determining at least one of the at least one electrochemical cell is in the late-life stage based on the lowest voltage.

3. The method of claim 1, further comprising:
determining the lowest voltage of at least one of the at least one electrochemical cell measured while powering the at least one load is at or below a minimum-voltage threshold; and
outputting a warning indication based on the determination that the lowest voltage is below the minimum-voltage threshold.

4. The method of claim 1, wherein monitoring the voltage of the at least one electrochemical cell while powering the at least one load comprises:
monitoring the voltage of the at least one electrochemical cell while powering at least one component in a device, the method further comprising:
providing at least one plot of minimum-powering voltages as a function of temperature for the respective at least one component; and
selecting the minimum-voltage threshold based on a current temperature of one of: at least one of the at least one electrochemical cell; the device; and the at least one component.

5. The method of claim 1, wherein monitoring the voltage of the at least one electrochemical cell while powering the at least one load comprises:
monitoring the voltage of the at least one electrochemical cell while powering at least one component in a device, the method further comprising:
collecting at least one minimum-powering voltage from a respective at least one datasheet associated with the at least one component;
selecting a crossover-threshold voltage between proper operation and improper operation of the at least one component; and
adding a safety margin to the crossover threshold voltage to obtain the minimum-voltage threshold.

6. The method of claim 1, wherein monitoring the voltage of the at least one electrochemical cell while powering the at least one load comprises:
monitoring the voltage of the at least one electrochemical cell while powering at least one component in a device, the method further comprising:
indicating at least one of the at least one electrochemical cell is in a late-life stage when one of the lowest voltages is within a safety margin of a minimum-voltage threshold of the at least one component in the device.

7. The method of claim 6, the method further comprising:
selecting the minimum-voltage threshold to match a minimum-powering voltage of a logic chip used in the at least one component.

8. The method of claim 6, the method further comprising:
selecting the minimum-voltage threshold to match a minimum-powering voltage of a regulator controller for a power supply circuit that powers the at least one component.

9. The method of claim 6, the method further comprising:
selecting the minimum-voltage threshold of the at least one component with a selected safety margin above a minimum-powering voltage specified to avoid circuit malfunctions.

10. The method of claim 6, the method further comprising:
selecting the minimum-voltage threshold below which a circuit in the at least one component is incapable of powering according to an intended function across a desired temperature range.

11. The method of claim 1, wherein monitoring the voltage of the at least one electrochemical cell while powering the at least one load comprises:
monitoring the voltage of the at least one electrochemical cell while powering at least one component in a device, the method further comprising:
measuring a temperature of at least one of: at least one of the at least one electrochemical cell; at least one of the at least one component; and the device; and
determining at least one of the at least one electrochemical cell is in the late-life stage based on a current temperature of the at least one of: the at least one of the at least one electrochemical cell; the at least one of the at least one component; and the device.

12. The method of claim 1, wherein monitoring the voltage of the at least one electrochemical cell while powering the at least one load comprises:
monitoring the voltage of the at least one electrochemical cell while powering at least one component in a device, the method further comprising:
periodically measuring a temperature of at least one of: at least one of the at least one electrochemical cell; at least one of the at least one component; and the device;
recording the periodically measured temperatures; and
determining at least one of the at least one electrochemical cell is in the late-life stage based on the recording of the measured temperatures of the at least one of: the at least one of the at least one electrochemical cell; the at least one of the at least one component; and the device.

13. The method of claim 1, further comprising:
determining the lowest voltage of at least one of the at least one electrochemical cell measured, while powering the at least one load, is above a minimum-voltage threshold; and
outputting a cell-OK indication based on the determination that the lowest voltage is above the minimum-voltage threshold.

14. The method of claim 1, wherein the at least one electrochemical cell comprises at least one battery, wherein monitoring the voltage of the at least one electrochemical cell while powering the at least one load comprises:
periodically measuring a voltage of the at least one battery while powering the at least one component.

15. The method of claim 1, wherein monitoring the voltage of the at least one electrochemical cell while powering the at least one load comprises:
monitoring the voltage of the at least one electrochemical cell while powering at least one component in a device, the method further comprising:
measuring a temperature of the device at a temperature sensor;
inputting information indicative of the measured temperature of the device to a processor.

16. The method of claim 1, further comprising:
selecting a maximum-voltage value and a minimum-voltage value for a desired voltage range of the at least one electrochemical cell,
wherein monitoring the voltage of the at least one electrochemical cell while powering the at least one load comprises:
collecting the lowest voltage of at least one of the at least one electrochemical cell determined while powering the at least one load,
the method further comprising:
calculating a remaining life value based on the selected maximum-voltage value, the minimum-voltage value and the determined lowest voltage; and
outputting the remaining life value.

17. A system to determine if at least one electrochemical cell is in a late-life stage of a life of the at least one electrochemical cell, the method comprising:
at least one measuring component to measure a voltage of at least one electrochemical cell while the at least one electrochemical cell is powering at least one load; and
at least one processing component to record the measured at least one voltage, to determine a lowest voltage of the at least one electrochemical cell measured while powering the at least one load, and to output a warning indication based on a determination that the lowest voltage is below a minimum-voltage threshold.

18. The system of claim 17, wherein the at least one processing component comprises:
a voltage recorder to record the measured at least one voltage and output the voltage; and
a processor to input the measured voltage from the voltage recorder, to determine the lowest voltage of the at least one electrochemical cell measured while powering the at least one load, and to output the warning indication based on the determination that the lowest voltage is below the minimum-voltage threshold.

19. The system of claim 17, wherein the at least one load is at least one powered component, the system further comprising:
a temperature sensor to measure a temperature of at least one of: the electrochemical cell; and the at least one component powered by the at least one electrochemical cell.

20. The system of claim 17, wherein the at least one load is at least one component, the system further comprising:
a temperature sensor to periodically measure a temperature of at least one of: the electrochemical cell; and the at least one component powered by the at least one electrochemical cell; and
a temperature recording device to input and record the measured temperatures and to output a lowest temperature to the processor.

21. The system of claim 17, wherein the at least one processing component comprises:
a voltage recorder to determine the lowest voltage of the at least one electrochemical cell measured while powering the at least one load, and to output the warning indication based on the determination that the lowest voltage is below the minimum-voltage threshold.

22. A method to determine if at least one battery is in a late-life stage of the at least one battery, the method comprising:
monitoring a voltage of the at least one battery while powering at least one component;
determining a lowest voltage of the at least one battery measured while powering the at least one component; and
determining at least one of the at least one battery is in the late-life stage based on the lowest voltage.

23. The method of claim 22, further comprising:
outputting a warning indication based on the determination that the lowest voltage is below a minimum-voltage threshold.

24. The method of claim 22, the method further comprising:
selecting a minimum-voltage threshold, wherein the selecting comprises one of:
selecting the minimum-voltage threshold to match a minimum-powering voltage of a logic chip used in the at least one component;
selecting the minimum-voltage threshold of a regulator controller for a power supply circuit that powers the at least one component;
selecting the minimum-voltage threshold of the at least one component to include a safety margin above a minimum-operational voltage specified to avoid circuit malfunctions in the at least one component;
selecting the minimum-voltage threshold above a minimum-operational voltage specified to permit a circuit to provide a desired function across a desired temperature range.

25. The method of claim 22, wherein monitoring the voltage of the at least one electrochemical cell while powering the at least one load comprises:
monitoring the voltage of the at least one electrochemical cell while powering at least one component in a device, the method further comprising:
providing plots of minimum-powering voltages as a function of temperature; and
selecting a minimum-voltage threshold based on a current temperature of one of: at least one of the at least one electrochemical cell; the device; and the at least one component.

26. The method of claim 22, further comprising:
collecting minimum-powering voltages from at least one datasheet associated with the at least one component;
selecting a crossover-threshold voltage between proper operation and improper operation of the at least one component; and
adding a safety margin to the crossover threshold voltage to obtain a minimum-voltage threshold.

27. The method of claim 22, wherein monitoring the voltage of the at least one battery while powering the at least one component comprises:
monitoring the voltage of the at least one battery while powering at least one component in a device, the method further comprising:
indicating at least one of the at least one battery is in the late-life stage when one of the lowest voltages approaches the voltage requirements of the at least one component in the device.

28. The method of claim 22, the method further comprising:
measuring a temperature of at least one of: at least one of the at least one battery; at least one of the at least one component; and the device; and
determining at least one of the at least one battery is in the late-life stage based on a current temperature of at least one of: the at least one of the at least one electrochemical cell; the at least one of the at least one component; and the device.

29. The method of claim 22, further comprising:
selecting a maximum-voltage value and a minimum-voltage value for a desired voltage range of the at least one battery, wherein monitoring a voltage of the at least one battery while powering at least one component comprise:
collecting the lowest voltage of at least one of the at least one battery determined while powering the at least one component,
the method further comprising:
calculating a remaining life value based on the selected maximum-voltage value, the minimum-voltage value and the collected lowest voltage; and
outputting the remaining life value.
